(19) United States
(12) Patent Application Publication
(10) Pub. No.: US 2015/0226786 A1
(43) Pub. Date: Aug. 13, 2015

(54) SEMICONDUCTOR SYSTEM AND OPERATING METHOD THEREOF

(71) Applicant: SK hynix Inc., Gyeonggi-do (KR)

(72) Inventors: Seung-Geun BAEK, Gyeonggi-do (KR); Hoon CHOI, Gyeonggi-do (KR)

(21) Appl. No.: 14/453,422

(22) Filed: Aug. 6, 2014

(30) Foreign Application Priority Data
Feb. 12, 2014 (KR) 10-2014-0016103

(51) Int. Cl. G01R 31/26

(52) U.S. Cl. CPC G01R 31/2607

(57) ABSTRACT

A semiconductor system includes a semiconductor device suitable for generating measuring data, and a controller suitable for comparing the measuring data with a given expected value and controlling a voltage level, which is supplied to the semiconductor device, based on the comparison result.

### CROSS-REFERENCE TO RELATED APPLICATIONS

The present application claims priority of Korean Patent Application No. 10-2014-0016103, filed on Feb. 12, 2014, which is incorporated herein by reference in its entirety.

### BACKGROUND

1. Field

Various embodiments of the present invention relate to a semiconductor design technology and, more particularly, to a semiconductor system for performing a data transfer operation.

2. Description of the Related Art

Semiconductor devices, such as double data rate synchronous DRAM (DDR DRAM), generally receive a power voltage from a controller and generate an internal voltage by using the power voltage. Internal voltages may be generated by a down-converting method or a pumping method. The internal voltages generated by the down-converting method include a core voltage, which is used in storing data in the semiconductor memory device, and a precharge voltage, which is used in precharge operations on bit lines. The internal voltages generated by the pumping method include a boosted voltage, which is applied to a gate of a cell transistor, and a negative voltage, which is applied to a substrate (or bulk) of the cell transistor.

FIG. 1 is a block diagram illustrating a conventional semiconductor system.

Referring to FIG. 1, the semiconductor system includes a controller 110, a memory block 120 and a power supply circuit 130, The memory block 120 includes a plurality of semiconductor memory devices.

The controller 110 controls the semiconductor devices. Channels for transmitting and receiving data DATA1, DATA2, . . . and DATn, where ‘n’ is a natural number, are disposed between the controller 110 and the respective semiconductor memory devices. The memory devices receive and store data DAT1, DAT2, . . . and DATn, provided from the controller 110, and output the stored data in response to the control of the controller 110. The power supply circuit 130 provides a power supply voltage VDD to the semiconductor memory devices.

As fabrication processes have been developed, the size of semiconductor device circuits has been reduced and the operation speed of the circuits has increased. In order to operate a highly integrated circuit at high speed, the voltage levels used in circuit operations need to be lowered. Thus, recently, technologies for generating and controlling low voltages have been developed.

### SUMMARY

Various embodiments of the present invention are directed to a semiconductor memory system for controlling voltages provided to a semiconductor device based on the data transfer state of the semiconductor device.

In accordance with an embodiment of the present invention, a semiconductor system may include a semiconductor device suitable for generating measuring data, and a controller suitable for comparing the measuring data with a given expected value and controlling the level of the voltage, which is supplied to the semiconductor device, based on the comparison result.

In accordance with another embodiment of the present invention, a semiconductor system may include a plurality of semiconductor devices and a controller suitable for comparing measuring data outputted from the respective semiconductor devices with a given expected value, and controlling a plurality of reference voltages supplied to the respective semiconductor devices.

In accordance with another embodiment of the present invention, an operating method of a semiconductor system may include storing measuring data that is received from a controller in a semiconductor device, outputting the stored measuring data to the controller, comparing the output measuring data with a given expected value, and adjusting the voltage level, which is supplied to the semiconductor device, based on the comparison result.

### BRIEF DESCRIPTION OF THE DRAWINGS

FIG, 1 is a block diagram illustrating a conventional semiconductor system.

FIG. 2 is a block diagram illustrating a semiconductor system in accordance with an embodiment of the present invention.

FIG. 3 is a block diagram illustrating a semiconductor system in accordance with an embodiment of the present invention.

FIG. 4 is a block diagram for describing an operation method of a semiconductor system in accordance with an embodiment of the present invention.

### DETAILED DESCRIPTION

Exemplary embodiments of the present invention will be described below in more detail with reference to the accompanying drawings. The present invention may, however, be embodied in different forms and should not be construed as limited to the embodiments set forth herein, Rather, these embodiments are provided so that this disclosure will be thorough and complete, and will fully convey the scope of the present invention to those skilled in the art. Throughout the disclosure, reference numerals correspond directly to the like parts in the various figures and embodiments of the present invention.

The drawings are not necessarily to scale and, in some instances, proportions may have been exaggerated in order to clearly illustrate features of the embodiments. In this specification, specific terms have been used. The terms are used to describe the present invention and are not used to qualify the sense or limit the scope of the present invention.

It is also noted that in this specification, ‘and/or’ represents that one or more of components arranged before and after ‘and/or’ is included. Furthermore, “connected/coupled” refers to one component not only directly coupling another component but also indirectly coupling another component through an intermediate component. In addition, a singular form may include a plural form, and vice versa, as long as it is not specifically mentioned. Furthermore, ‘include/comprise’ or ‘including/comprising’ used in the specification represents that one or more components, steps, operations, and elements exists or are added.

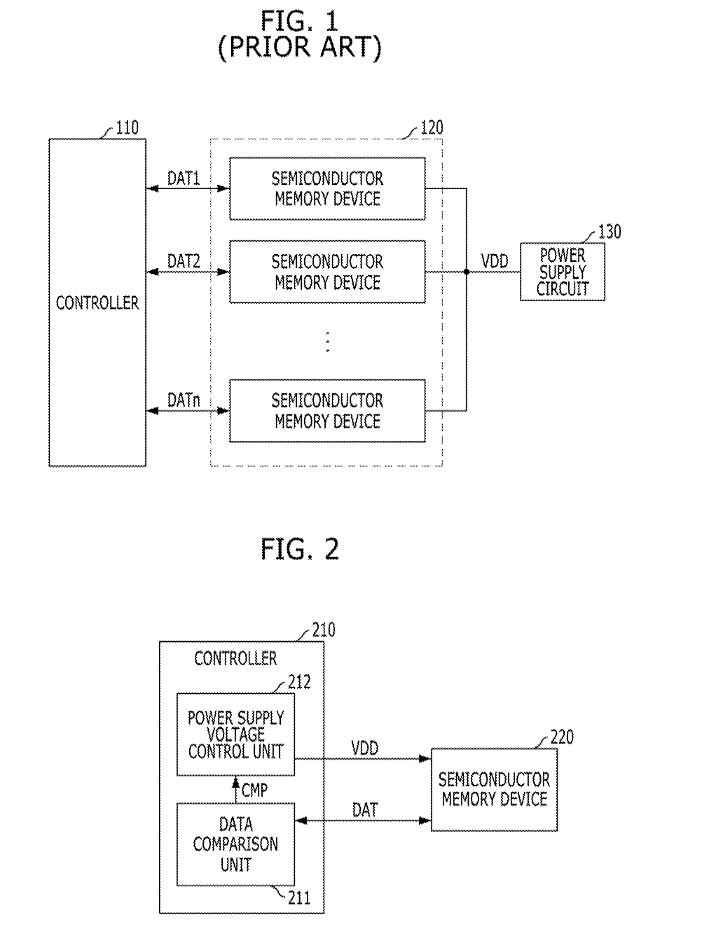

FIG. 2 is a block diagram illustrating a semiconductor system in accordance with an embodiment of the present invention.

Referring to FIG. 2, the semiconductor system may include a controller 210 and a semiconductor memory device 220.

The controller 210 controls the semiconductor memory device 220. The controller 210 may include a data comparison unit 211 and a power supply voltage control unit 212. The data comparison unit 211 compares measuring data DAT with a given expected value, and generates a comparison result CMP. The power supply voltage control unit 212 controls (or adjusts) the voltage level of a power supply voltage VDD in response to the comparison result CMP. The given expected value is a value predetermined by the controller 210 and the semiconductor memory device 220. The controller 210 determines if the power supply voltage VDD supplied to the semiconductor memory device 220 is optimum to output the measuring data DAT by comparing the given expected value with the measuring data DAT.

Hereinafter, the test mode for controlling the voltage level of the power supply voltage VDD is referred to as ‘a measuring mode’. That is, in the measuring mode, the AC characteristics of data output is measured (or tested) and adjusted by controlling the voltage level of the power supply voltage VDD.

The semiconductor memory device 220 performs a circuit operation, for example, a read operation, using the power supply voltage VDD provided from the controller 210. The semiconductor memory device 220 provides the measuring data DAT to the controller 210 during the measuring mode, and the logic level of the measuring data DAT is determined according to the power supply voltage VDD. In other words, the measuring data DAT may be an indication for determining a data transfer state according to the power supply voltage VDD. That is, during the measuring mode, the semiconductor memory device 220 transfers the data transfer state to the controller 210 using the measuring data DAT, and the controller 210 controls (or adjusts) the voltage level of the power supply voltage VDD according to the data transfer state.

Hereinafter, a circuit operation of the semiconductor system will be described.

During the measuring mode, the semiconductor memory device 220 outputs the measuring data DAT, The controller 210 compares the measuring data DAT with the given expected value stored in the controller 210, and controls the voltage level of the power supply voltage VDD. The power supply voltage VDD is adjusted until the measuring data DAT becomes the same as the given expected value. After the adjustment is completed, that is, when the pilot mode is terminated, the adjusted power supply voltage may have a voltage level that optimizes the data transfer state.

The semiconductor system in accordance with an embodiment of the present invention may provide optimized conditions for data transfer by controlling the voltage level of the power supply voltage VDD based on the data transfer state of the semiconductor memory device 220.

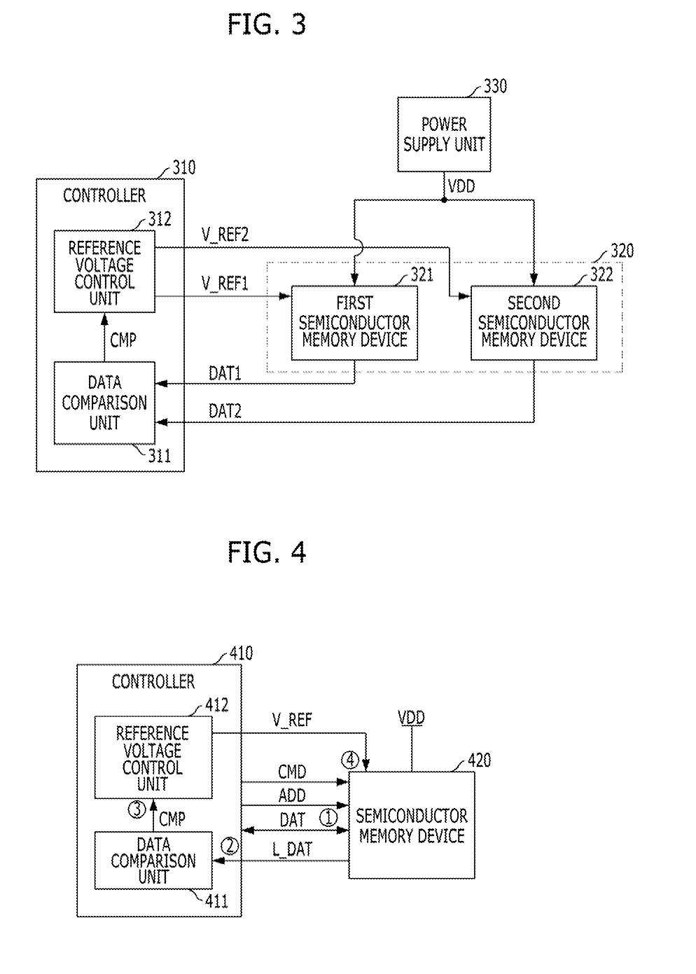

FIG. 3 is a block diagram illustrating a semiconductor system in accordance with an embodiment of the present invention.

Referring to FIG. 3, the semiconductor system may include a controller 310, a memory block 320 and a power supply unit 330, The memory block 320 includes a plurality of semiconductor memory devices 321 and 322.

The controller 310 controls the semiconductor memory devices 321 and 322. The controller 310 may include a data comparison unit 311 and a reference voltage control unit 312. The data comparison unit 311 compares a first measuring data DAT1 outputted from a first semiconductor device 321 with a given expected value, compares a second measuring data DAT2 outputted from a second semiconductor device 322 with the given expected value, and generates a comparison result CMP. The reference voltage control unit 312 controls (or adjusts) the voltage level of a first reference voltage V_REF1 and the voltage level of a second reference voltage V_REF2 in response to a comparison result.

The first semiconductor device 321 performs a circuit operation by using the first reference voltage V_REF1. The second semiconductor device 322 performs a circuit operation by using the second reference voltage V_REF2. For example, the first semiconductor device 321 and the second semiconductor device 322 may generate an internal voltage in response to the first, reference voltage V_REF1 and the second reference voltage V_REF2, respectively. The first reference voltage V_REF1 and the second reference voltage V_REF2 may be a reference for determining a logic level of data used in the first semiconductor device 321 and the second semiconductor device 322, respectively.

The power supply unit 330 provides the power supply voltage VDD to the first semiconductor device 321 and the second semiconductor device 322. That is, the first semiconductor device 321 and the second semiconductor device 322 receive the power supply voltage VDD and may set the first reference voltage V_REF1 and the second reference voltage V_REF2 to have different voltage levels from each other.

As the semiconductor system in accordance with the embodiment of the present invention shown in FIG. 3 is compared with the semiconductor system in accordance with the embodiment of the present invention shown in FIG. 2, the semiconductor system in accordance with the embodiment of the present invention shown in in FIG. 2 may adjust the voltage level of the power supply voltage VDD according to the data transfer state, and the semiconductor system in accordance with the embodiment of the present invention shown in FIG. 3 may adjust the voltage level of the first reference voltage V_REF1 and the second reference voltage V_REF2 according to the data transfer state.

In the embodiment of the present invention shown in FIG. 2, the power supply voltage control unit 212 may correspond to a driving circuit for driving the power supply voltage VDD.

As described above, the given expected value must be preset in the controller 310, the first semiconductor device 321 and the second semiconductor device 322.

FIG. 4 is a block diagram for describing an operation method of a semiconductor system in accordance with an embodiment of the present invention. For convenience, only one semiconductor memory device 420 for receiving a power supply voltage VDD will be exemplarily described.

Referring to FIG. 4, the controller 410 controls the semiconductor memory device 420. The controller 410 transfers a command signal CMD, an address signal ADD and a data signal DAT to the semiconductor memory device 420. The semiconductor memory device 420 stores the data signal DAT at a location corresponding to the address signal ADD or outputs the stored data in response to the command signal CMD. In the embodiment of the present invention shown in FIG. 4, the voltage level of the reference voltage V_REF may be adjusted based on the data transfer state.

Hereinafter, a measuring mode operation of the semiconductor system will be described.

In the measuring mode, the semiconductor memory device 420 receives the measuring data DAT from the controller 410 and stores the measuring data DAT in a predetermined location \textcircled{1}. The predetermined location may be a memory region defined by the address signal ADD and may be a storage region that is activated during the measuring mode. Then, the semiconductor memory device 420 feeds back the stored data L_DATA to the controller 410 \textcircled{2}. The stored data L_DATA is compared with the measuring data DAT, that is, the given expected data, by the data comparison unit 411. The data comparison unit 411 outputs a comparison signal CMP as the comparison result \textcircled{3}. Subsequently, the reference voltage control unit 412 adjusts the voltage level of the reference voltage V_REF in response to the comparison signal CMP \textcircled{4}. Since the measuring data DAT is a data value generated by the controller 410, the controller 410 and the semiconductor memory device 420 may share the measuring data DAT.

The above-mentioned process is performed until the measuring data DAT is the same as the stored data L_DATA. That is, until the stored data L_DAT on the semiconductor memory device 420 becomes the same as the measuring data, the reference voltage V_REF is adjusted. The reference voltage V_REF may then be adjusted to be an optimum voltage level to suit the data transfer state of the controller 410 and the semiconductor memory device 420.

As described above, a semiconductor system in accordance with an embodiment of the present invention may change data transfer conditions according to the data transfer state. This means that the data transfer conditions may be adjusted to suit changing temperatures, processes and voltages. That is, the semiconductor system in accordance with an embodiment of the present invention may increase data transfer operation efficient and improve the reliability of the transferred data.

While the present invention has been described with respect to specific embodiments, it will be apparent to those skilled in the art that various changes and modifications may be made without departing from the spirit and scope of the invention as defined in the following claims.

What is claimed is:

1. A semiconductor system, comprising:
a semiconductor device suitable for generating measuring data; and
a controller suitable for comparing the measuring data with a given expected value and controlling a voltage level of a voltage, which is supplied to the semiconductor device, based on the comparison result.

2. The semiconductor system of claim wherein the voltage is a power supply voltage.

3. The semiconductor system of claim 1, wherein the measuring data is stored in the semiconductor device by the controller.

4. The semiconductor system of claim wherein the voltage is a reference voltage.

5. The semiconductor system of claim 2, wherein the controller comprises:
a data comparison unit suitable for comparing the measuring data with the given expected value; and
a power supply voltage control unit suitable for controlling a voltage level of the power supply voltage in response to an output signal of the data comparison unit.

6. A semiconductor system, comprising:
a plurality of semiconductor devices; and
a controller suitable for comparing a plurality of measuring data outputted from the respective semiconductor devices with a given expected value, and controlling a plurality of reference voltages supplied to the respective semiconductor devices.

7. The semiconductor system of claim 6, further comprising:
a power supply unit suitable for commonly providing a power voltage to the semiconductor devices.

8. The semiconductor system of claim 6, wherein the measuring data is stored in the semiconductor devices by the controller.

9. The semiconductor system of claim 6, wherein the controller comprises:
a data comparison unit suitable for comparing the measuring data with the given expected value; and
a reference voltage control unit suitable for controlling voltage levels of the respective reference voltages in response to an output signal of the data comparison unit.

10. An operating method of a semiconductor system, comprising:
storing a measuring data, received from a controller, in a semiconductor device;
outputting the stored measuring data to the controller;
comparing the outputted measuring data with a given expected value; and
adjusting a voltage level of a voltage, which is supplied to the semiconductor device, based on the comparison result.

11. The operating method of claim 10, wherein the voltage is a power supply voltage.

12. The operating method of claim 10, wherein the voltage is a reference voltage.
